(19) United States
(12) Patent Application Publication
(10) Pub. No.: US 2026/0090103 A1
(43) Pub. Date: Mar. 26, 2026

(54) DISPLAY PANEL AND DISPLAY APPARATUS

(71) Applicant: WUHAN CHINA STAR OPTOELECTRONICS TECHNOLOGY CO., LTD., Wuhan, Hubei (CN)

(72) Inventors: Huicong LI, Wuhan, Hubei (CN); Qiang HE, Wuhan, Hubei (CN)

(73) Assignee: WUHAN CHINA STAR OPTOELECTRONICS TECHNOLOGY CO., LTD., Wuhan, Hubei (CN)

(21) Appl. No.: 18/557,949

(22) PCT Filed: Jun. 30, 2023
(86) PCT No.: PCT/CN2023/104813

§ 371 Date: Oct. 29, 2023

(30) Foreign Application Priority Data
May 30, 2023 (CN) 202310624742.0

(51) Int. Cl. H10D 86/40; G02F 1/1343; G02F 1/1362; G02F 1/1368; H10D 86/60

(52) U.S. Cl. CPC H10D 86/441; G02F 1/134309; G02F 1/136209; G02F 1/136286; G02F 1/1368; H10D 86/60

(57) ABSTRACT

A display panel includes a plurality of data lines and a plurality of scan lines, the plurality of data lines and the plurality of scan lines enclose a plurality of pixel units, the pixel units each includes a pixel electrode, and an included acute angle between a branch electrode of a pixel electrode and an adjacent data line is greater than 0° and less than or equal to 7°.

### TECHNICAL FIELD

The present application relates to a field of display technologies, and in particular, to a display panel and a display apparatus.

### BACKGROUND

In a liquid crystal display (LCD) display product, fringe field switching (FFS) is an in-plane switching type display mode, which generates an edge electric field by using a top-layer pixel electrode and a bottom-layer common electrode on an array substrate, so that each liquid crystal molecule between the electrodes and each liquid crystal molecule directly above the electrodes may rotate on a plane parallel to the substrate.

Currently, the smaller a tilt angle of the pixel electrode in the FFS-type display panel is, the lower a brightness of a black screen of and the higher a contrast of the display panel, o while the longer a response time of switching a display screen will be. The larger the tilt angle of the pixel electrode, the shorter the response time for the display panel to switch between gray levels, and the less prone to smear when a screen is switched. However, the higher the brightness of the black screen of the display panel, the lower the contrast. Therefore, how to balance the contrast of the display panel and the response time of switching a display screen is a technical problem that needs to be urgently resolved.

### SUMMARY OF THE INVENTION

The present application provides a display panel and a display apparatus, to improve a technical problem that the contrast of the display panel and the response time of switching a display screen cannot be balanced.

To solve the above problems, the technical solutions provided in the present application are as follows.

The present application provides a display panel, including a plurality of data lines and a plurality of scan lines, where the plurality of data lines and the plurality of scan lines enclose a plurality of pixel units, and the pixel units each comprises a pixel electrode.

The pixel electrode includes a plurality of slits and a plurality of branch electrodes disposed between the plurality of slits, and an included acute angle between one of the branch electrodes and an adjacent data line is greater than 0° and less than or equal to 7°.

The present application further provides a display apparatus. The display apparatus includes a display panel and a backlight module disposed on one side of the display panel; where the display panel comprises a plurality of data lines and a plurality of scan lines, the plurality of data lines and the plurality of scan lines enclose a plurality of pixel units, and the pixel units each comprises a pixel electrode.

The pixel electrode includes a plurality of slits and a plurality of branch electrodes disposed between the plurality of slits, and an included acute angle between one of the branch electrodes and an adjacent data line is greater than 0° and less than or equal to 7°.

### DESCRIPTION OF THE DRAWINGS

FIG. 1 is a diagram showing a first structure of a single-domain pixel electrode in a display panel according to the present application;

FIG. 2 is a cross-sectional view of the display panel according to the present application;

FIG. 3 is a schematic structural diagram of the display panel according to the present application;

FIG. 4 is a diagram showing different light leakage experiments of a thin film transistor and an orthogonal polarizer of the display panel according to the present application;

FIG. 5 is a diagram showing a first structure of a dual-domain pixel electrode in the display panel according to the present application;

FIG. 6 is a diagram showing a second structure of a single-domain pixel electrode in the display panel according to the present application;

FIG. 7 is a diagram showing a third structure of a single-domain pixel electrode in the display panel according to the present application;

FIG. 8 is a diagram showing a fourth structure of a single-domain pixel electrode in the display panel according to the present application;

FIG. 9 is a diagram showing a second structure of a dual-domain pixel electrode in the display panel according to the present application;

FIG. 10 is a diagram showing a first pixel electrode structure in different areas in the display panel according to the present application;

FIG. 11 is a diagram showing a second pixel electrode structure in different areas in the display panel according to the present application;

FIG. 12 is a schematic structural diagram of a display apparatus according to the present application.

### EMBODIMENTS OF THE INVENTION

To make the objectives, technical solutions, and effects of the present application more clear and explicit, the following further describes the present application in detail with reference to an accompanying drawings and embodiments. It should be understood that specific embodiments described herein are only used to explain the present application, and are not used to limit the present application.

Currently, a tilt angle of a pixel electrode in an FFS-type display panel is negatively related to a contrast of the display panel and a response time of switching a display screen. Therefore, a display panel with a low response time and a high contrast may not be implemented at the same time. The following technical solutions are proposed in the present application to ameliorate the above technical problems.

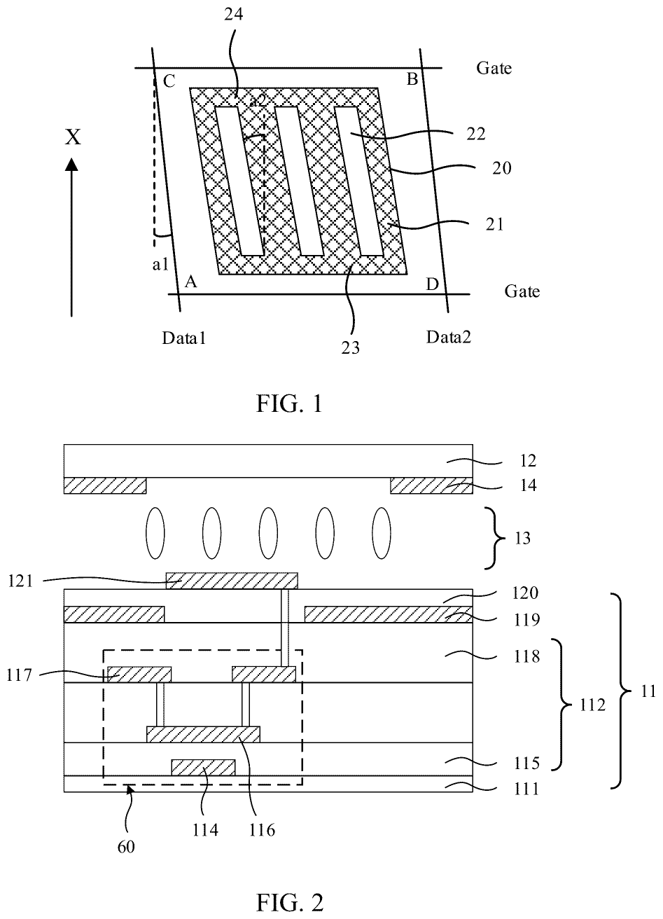

Referring to FIG. 1 to FIG. 11, the present application provides a display panel 100, where the display panel 100 may include a plurality of scan lines Gate and a plurality of data lines Data, and the plurality of data lines Data and the plurality of scan lines Gate enclose a plurality of pixel units 10.

In one or more embodiments, the pixel unit 10 includes a pixel electrode 20, the pixel electrode 20 includes a plurality of slits 22 and a plurality of branch electrodes 21 disposed between the plurality of slits 22, and an included acute angle between a branch electrode 21 and an adjacent data line Data is greater than 0° and less than or equal to 7°.

In the present application, an angle of the data line Data is changed, so that an included acute angle between the branch electrode 21 and the adjacent data line Data is greater than 0° and less than or equal to 7°, polarization scattering effect of the data line Data on light is reduced, light leakage of the light on the data line Data is reduced. Brightness of a black screen of the display panel 100 is improved, contrast of the display panel 100 is improved. A technical problem that the contrast of the display panel 100 and the response time of switching a display screen cannot be balanced is resolved.

It should be noted that the tilt angle of the pixel electrode 20 is an included acute angle between the branch electrode 21 in the pixel electrode 20 and a first direction X. And the first direction X is perpendicular to the scan lines Gate. For example, in the structure shown in FIG. 1, the first direction X and the scan lines Gate of the display panel 100 are parallel.

The technical solutions of the present application are described with reference to specific embodiments.

Referring to FIG. 2, FIG. 2 is a cross-sectional view of the display panel 100.

In one or more embodiments, the display panel 100 may include an array substrate 11, a color film substrate 12 disposed opposite to the array substrate 11, and a liquid crystal layer 13 disposed between the array substrate 11 and the color film substrate 12. The array substrate 11 may be a conventional array substrate 11 or a Color filter on Array (COA, color film layer disposed on the array) substrate. This is not specifically limited in the present application. In the following embodiment, the conventional array substrate 11 is used as an example for description in the present application.

In one or more embodiments, the array substrate 111 may include a substrate 111 and a thin film transistor layer 112 located on the substrate 111. A material of the substrate 111 may be prepared from a material such as glass, quartz, or polyimide.

In one or more embodiments, the thin film transistor layer 112 may include a plurality of thin film transistors 140. The thin film transistors 140 may have a structure such as an etch-stop barrier structure, a back-channel-etched structure, or a top-gate thin film transistor structure, which is not specifically limited in the present application. For example, the thin film transistor 140 of a bottom-gate thin film transistor type may include a gate layer 114 on the first substrate 111, a gate insulating layer 115 on the gate layer 114, a semiconductor layer 116 on the gate insulating layer 115, a source-drain layer 117 on the semiconductor layer 116, a planarization layer 118 on the source-drain layer 117, a common electrode layer 119 on the planarization layer 118, a passivation layer 120 on the common electrode layer 119, and a pixel electrode layer 121 on the passivation layer 120.

In one or more embodiments, locations of the pixel electrode layer 121 and the common electrode layer 119 may be interchanged.

In one or more embodiments, the gate layer 114 may include a gate and a scan line Gate. The source-drain layer may include a source, a drain, a data line Data, and the like. A plurality of data lines and a plurality of scan lines enclose to form a plurality of pixel units.

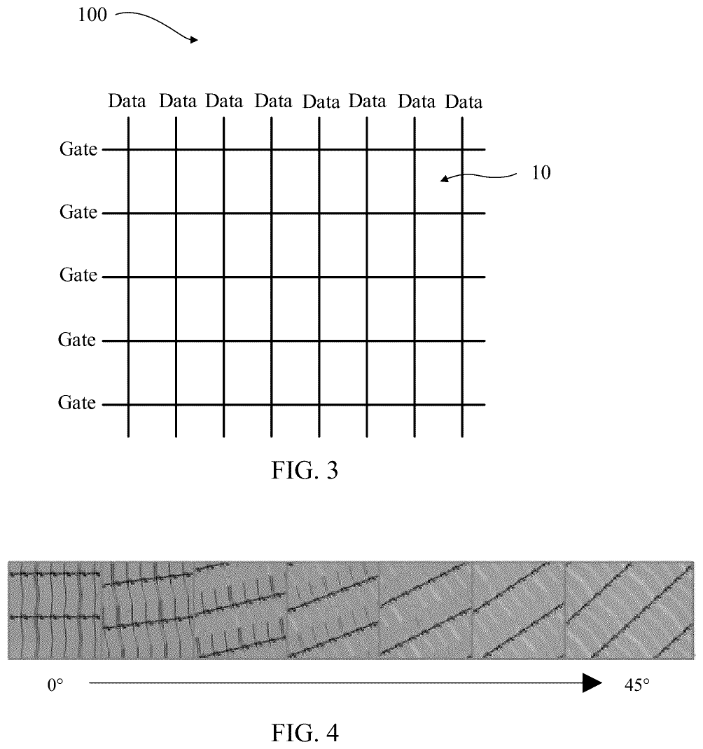

In one or more embodiments, referring to FIG. 3, a plurality of scan lines Gate and a plurality of data lines Data divide the display panel 100 into a plurality of pixel units 10. The pixel electrode 20 is disposed in each of the pixel units 10. That is, the pixel electrode layer 121 is divided into the plurality of pixel electrodes 20 by the plurality of scan lines Gate and the plurality of data lines Data. An orthographic projection of the pixel electrode 20 on the common electrode layer 119 is located in the common electrode layer 119, and a voltage difference between the pixel electrode 20 and the common electrode layer 119 drives deflection of liquid crystal molecules in the liquid crystal layer 13.

In an existing FFS-type display panel 100, the pixel electrode 20 is usually a single-domain design. However, to improve a viewing angle problem of the display panel 100, there are more and more multi-domain designs. The following embodiment first describes the technical solutions of the present application by using a single-domain design as an example.

In the prior art, the included acute angle a2 between the branch electrode 21 in the pixel electrode 20 and the first direction X is usually set to 5° and 7°. When the included acute angle a2 between the branch electrode 21 and the first direction X is 5°, the brightness of a black screen of the display panel 100 is low and the contrast of the display panel 100 is at a better value, but the response time for switching a display screen is relatively long. When the included acute angle between the branch electrode 21 and the first direction X is 7°, the response time for switching between gray levels of the display panel 100 is relatively short, and smearing does not easily occur during screen switching. However, the brightness of the black screen of the display panel 100 is relatively high, and the contrast decreases. Improvement of the response time for switch a display screen needs to change a structure, a driving algorithm, and the like of the thin film transistor, which is relatively complex.

In the display panel 100 of the present application, referring to FIG. 1, the included acute angle a2 between the branch electrode 21 and the first direction X is 7°, and the included acute angle al between the data line Data and the first direction X is greater than or equal to 0° and less than 7°. For example, the included acute angle al between the data line Data and the first direction X is 0°, 1°, 2°, 3°, 4°, 5°, 6°, Or the like.

In one or more embodiments, the included acute angle a2 between the branch electrode 21 and the first direction X may be 7°. At this angle, the response time for switching between gray levels of the display panel 100 is relatively short, and smearing does not easily occur during screen switching. In addition, because the branch electrode 21 is at this angle, the brightness of the black screen of the display panel 100 is relatively high, and the contrast decreases. Therefore, to improve contrast of the display panel 100, in the present application, a tilt angle of the data line Data that is disposed in parallel with the branch electrode 21 is changed, for example, to make the included acute angle al between the data line Data and the first direction X to be greater than or equal to 0° and less than 7°, so as to reduce polarization scattering of light by the data line Data, reduce light leakage of light on the data line Data, improve the brightness of black screen of the display panel 100, and improve the contrast of the display panel 100.

Referring to FIG. 4, the structure in FIG. 4 is a diagram showing different light leakage experiments of a thin film transistor and an orthogonal polarizer. In a direction from left to right, the thin film transistor rotates from 0° to 45°. It can be learned from the structure shown in the figure that when the thin film transistor is at 0°, light leaks the least on the data line Data, and the contrast of the display panel 100 is the best. When the thin film transistor is at 45°, light leaks the most on the data line Data, and the contrast of the display panel 100 is the worst. Therefore, the closer the thin film transistor is to 0°, the higher the contrast of the display panel 100 is. The closer the thin film transistor is to 45°, the lower the contrast of the display panel 100 is. However, in the present application, the included acute angle al between the data line Data and the first direction X is changed from an original 7° to be greater than or equal to 0° and less than 7°, which improves a light leakage situation of light on the data line Data, and improves the contrast of the display panel 100.

Referring to FIG. 1, the pixel electrode 20 may include a first vertex A and a second vertex B that are located on a first diagonal line, and a third vertex C and a fourth vertex D that are located on a second diagonal line. A spacing between the first vertex A and an adjacent data line Data and a spacing between the second vertex B and an adjacent data line Data are equal. A spacing between the third vertex C and an adjacent data line Data and a spacing between the fourth vertex D and an adjacent data line Data are equal. The spacing between the first vertex A and the adjacent data line Data and the spacing between the third vertex C and the adjacent data line Data are different.

In one or more embodiments, the display panel 100 includes a first data signal line Data1 and a second data signal line Data2 that are located on two sides of the pixel unit 10. The included acute angle between the data line Data and the first direction X decreases, so that the spacing between the first vertex A and the first data signal line Datal increases, the spacing between the second vertex B and the second data signal line Data2 increases, the spacing between the third vertex C and the first data signal line Data1 decreases, and the spacing between the fourth vertex D and the second data signal line Data2 decreases.

In the structure in FIG. 1, the spacing between the first vertex A, the second vertex B and the adjacent data lines Data is greater than the spacing between the third vertex C, the fourth vertex D and the adjacent data lines Data. Therefore, there is light leakage areas between the first vertex A and the second vertex B and the adjacent data lines Data, which causes a technical problem that the brightness is uneven due to light leakage inside the pixel unit 10.

In the structure in FIG. 1, the display panel 100 may further include a light shielding layer 14 that covers the data lines Data and some of the pixel units 10, and a location of the light shielding layer 14 is specifically limited in the present application. The light shielding layer 14 may cover the data lines Data and some of the pixel units 10. For example, the light shielding layer 14 may be disposed on the color film substrate. That is, in one or more embodiments, in addition to covering the corresponding data lines Data, the light shielding layer 14 further extends the first vertex A and the second vertex B of the pixel electrode 20, so as to shield the light leakage areas between the first vertex A, the second vertex B and the adjacent data lines Data, thereby avoiding a technical problem of light leakage in the pixel unit 10.

In one or more embodiments, the spacing between the first vertex A, the second vertex B and the adjacent light shielding layer 14 is equal to the spacing between the third vertex C, the fourth vertex D and the adjacent light shielding layer 14. For example, the spacing between the first vertex A and the adjacent light shielding layer 14 may be N, the spacing between the third vertex C and the adjacent light shielding layer 14 may be M, and the spacing N and the spacing M may be equal. The spacing between the shielding layer and the four vertices of the corresponding pixel electrode 20 is equal. The light leakage areas between the first vertex A, the second vertex B and the adjacent data lines Data are shielded, thereby improving light emission uniformity of the display panel 100.

In the structure in FIG. 1, the boundary of the light shielding layer 14 may be disposed in parallel with the boundary of the pixel electrode 20, that is, the boundary of the light shielding layer 14 and the corresponding boundary of the branch electrode 21 are disposed in parallel, so that an area of a non-shielded area around the pixel unit 10 is equal, and light emission uniformity of the display panel 100 is improved.

In the structure in FIG. 1, the included acute angle a2 between the branch electrode 21 and the first direction X is 7°, the included acute angle a1 between the data line Data and the first direction X is 5°, and the light shielding layer 14 is asymmetrically disposed on two sides of the pixel unit 10. In comparison with the prior art, the contrast in one or more embodiments is improved by 2.9%.

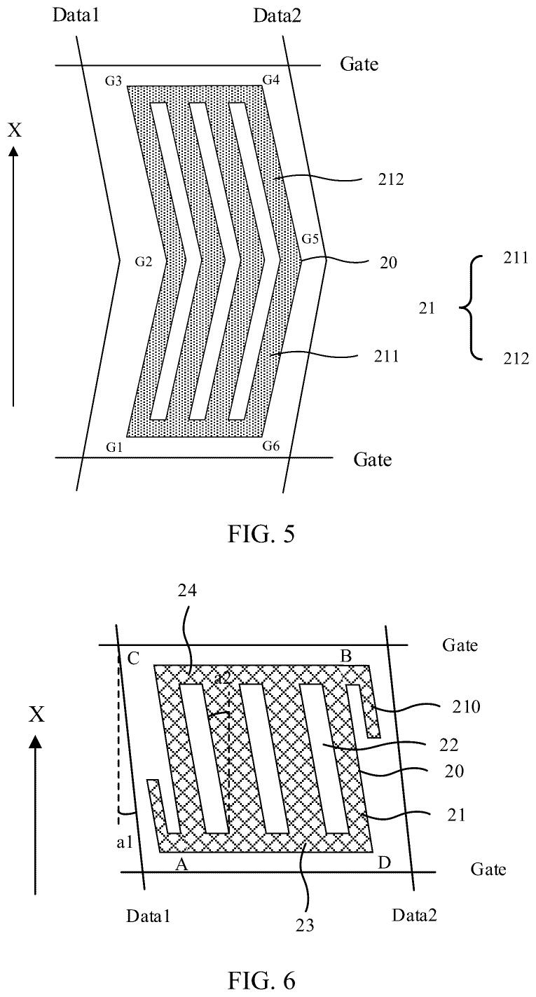

Referring to FIG. 5, the pixel electrode in FIG. 5 is a dual-domain design. The branch electrode includes a first branch 211 and a second branch 212. The first branch 211 and the second branch 212 are disposed at an included angle. The first branch 211 is corresponding to the first connection segment 301, the second branch 212 is corresponding to the second connection segment 302. The included acute angle between the first branch 211 and the first direction X may be the same as the included acute angle between the second branch 212 and the first direction X. For example, the included acute angle a2 between the branch electrode 21 and the first direction X is 7°, and the included acute angle al between the data line Data and the first direction X is 5°.

In one or more embodiments, the pixel electrode 20 may include a vertex G1, a vertex G2, a vertex G3, a vertex G4, a vertex G5, and a vertex G6 that are arranged in a clockwise direction. The vertex G2 and the vertex G5 are intersection points of the first branch and the second branch, and a spacing between the vertex G1, the vertex G3, and the vertex G5 and the adjacent data lines Data is less than a spacing between the vertex G2, the vertex G4, and the vertex G6 and the adjacent data lines Data. Therefore, light leakage areas exist between the vertex G2, the vertex G4, and the vertex G6 and the adjacent data lines Data. In the structure in FIG. 5, the light shielding layer 14 extends toward the vertex G2, the vertex G4, and the vertex G6, thereby reducing an area of the light leakage areas between the vertex G2, the vertex G4, and the vertex G6 and the adjacent data lines Data. The light shielding layer 14 is asymmetrically disposed on two sides of the pixel unit 10. Compared with the prior art, the contrast in one or more embodiments is improved by 3.0%, and light emission uniformity of the display panel 100 is improved.

In one or more embodiments, a boundary of the light shielding layer 14 may be disposed in parallel with a corresponding boundary of the branch electrode 21, so that an area of a peripheral non-shielded area of the pixel unit 10 is equal, thereby improving light emission uniformity of the display panel 100.

Referring to the structures in FIG. 6 to FIG. 8, in the pixel unit 10, the pixel electrode 210 further includes an edge electrode 210 disposed between the data line Data and the branch electrode 21. The edge electrode 210 is electrically connected to the branch electrode 21. The edge electrode 210 and the branch electrode 21 are disposed in parallel and separately. In an extension direction of the branch electrode, a length of the edge electrode 210 may be less than a length of the branch electrode 21.

In the structures in FIG. 6 to FIG. 8, a shape of the combined plurality of branch electrodes 21 is the same as a shape of the pixel electrode 20 in FIG. 1, and four vertices exist in the shape of the combined plurality of branch electrodes 21. However, because light leakage areas exists between the first vertex A and the second vertex B and the adjacent data lines Data, at least one edge electrode 210 is disposed in a light leakage area in the structure in FIG. 6 to FIG. 8, so that the light leakage area becomes a light transmission area of the pixel electrode 20. An area of the light leakage areas in the pixel unit 10 is reduced, and light emission uniformity of the display panel 100 is improved.

In addition, referring to the structures in FIG. 6 to FIG. 8, in one pixel unit 10, the pixel electrode 20 further includes a first transverse electrode 23 and a second transverse electrode 24. The first transverse electrode 23 and the second transverse electrode 24 may be parallel to the scan lines Gate. First ends of the plurality of branch electrodes 21 are connected to the first transverse electrode 23. Second end of the plurality of branch electrodes 21 are connected to the second transverse electrode 24. Two adjacent branch electrodes 21, the first transverse electrode 23, and the second transverse electrode 24 enclose the slit 22.

In one or more embodiments, a first end of the edge electrode 210 is connected to the first transverse electrode 23. A second end of the edge electrode 210 is separately disposed from the second transverse electrode 24. The edge electrode 210 and the adjacent branch electrode 210 do not enclose the slit 22.

In the structures in FIG. 6 to FIG. 8, lengths of the first transverse electrode 23 and the second transverse electrode 24 in the extension direction of the scan lines Gate may be equal. Compared with the corresponding first transverse electrode 23 and the second transverse electrode 24 in FIG. 1, the first transverse electrode 23 and the second transverse electrode 24 in FIG. 6 to FIG. 8 both extend toward an adjacent data line Data. For example, the first transverse electrode 23 extends toward the data line Data1, And the second transverse electrode 24 extends toward the data line Data2, so that a sufficient length is reserved to provide the corresponding edge electrode 210.

In the structure in FIG. 6, an included acute angle a2 between the branch electrode 21 and the first direction X is 7°, and an included acute angle al between the data line Data and the first direction X is 5°. Because an included acute angle between the branch electrode 21 and the data line Data is relatively small, only one edge electrode 210 is disposed in a light leakage area between the first vertex A and the second vertex B and the adjacent data lines Data, thereby reducing an area of the light leakage areas in the pixel unit 10. Compared with the prior art, the contrast in one or more embodiments is improved by 2.0%. When the contrast of the display panel 100 is improved, the brightness uniformity of the display panel 100 is improved.

In the structure in FIG. 6, in an extension direction of the branch electrode, a length of the edge electrode 210 is less than half a length of the branch electrode 21.

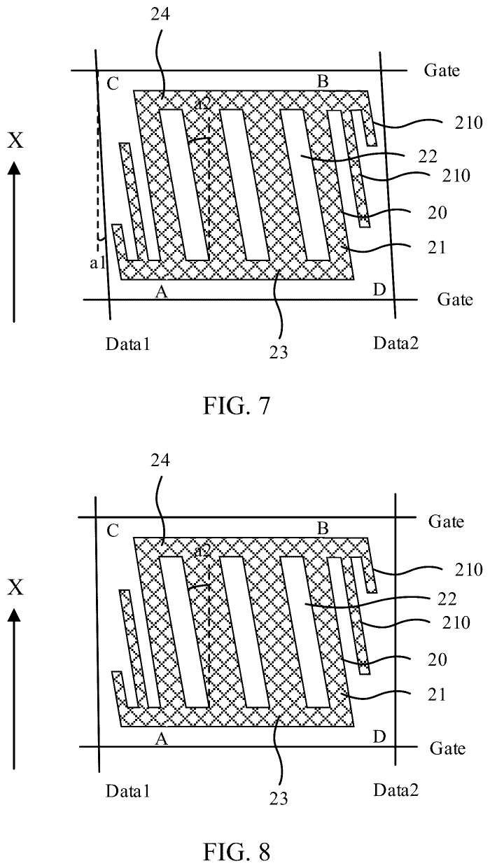

In the structure in FIG. 7, an included acute angle a2 between the branch electrode 21 and the first direction X is 7°. An included acute angle al between the data line Data and the first direction X is 3°. Because an included acute angle between the branch electrode 21 and the data line Data is increased compared with the structure in FIG. 6, an area of a light leakage areas between the first vertex A and the second vertex B and the adjacent data line Data is increased. Two edge electrodes 210 are disposed in each light leakage area, which reduces an area of the light leakage areas in the pixel unit 10. Compared with the prior art, the contrast in one or more embodiments is improved by 2.4%. When the contrast of the display panel 100 is improved, the brightness uniformity of the display panel 100 is improved.

In the structure in FIG. 8, an included acute angle a2 between the branch electrode 21 and the first direction X is 7°. An included acute angle al between the data line Data and the first direction X is 0°. Because an included acute angle between the branch electrode 21 and the data line Data is increased compared with the structure in FIG. 7, an area of a light leakage areas between the first vertex A and the second vertex B and the adjacent data lines Data is further increased. Two edge electrodes 210 are disposed in each light leakage area, which reduces an area of the light leakage areas in the pixel unit 10. Compared with the prior art, the contrast in one or more embodiments is improved by 2.7%. When the contrast of the display panel 100 is improved, the brightness uniformity of the display panel 100 is improved.

In the structures in FIG. 7 and FIG. 8, in an extension direction of the branch electrode, lengths of the two edge electrodes 210 are less than a length of the branch electrode 21, and a length of the edge electrode 210 close to the branch electrode 21 is greater than a length of the edge electrode 210 away from the branch electrode 21.

In the structures in FIG. 6 to FIG. 8, although the disposed edge electrodes 210 may reduce an area of the light leakage areas in the pixel unit 10, compared with the structure in FIG. 1, some light leakage areas still exist. In one or more embodiments, the boundary of the light shielding layer 14 and the boundary of the edge electrode 210 in the structures in FIG. 6 to FIG. 8 may be disposed in parallel. That is, the light shielding layer 14 in FIG. 6 to FIG. 8 extends to the first vertex A and the second vertex B, so that an area of the non-shielded area around the pixel unit 10 is equal, and the light emission uniformity of the display panel 100 is improved.

In the structures in FIG. 6 to FIG. 8, in an extension direction of the scan line Gate, a spacing between the edge electrode 210 and the adjacent branch electrode 21 may be less than a width of the slit 22, to set more edge electrodes 210, so as to reduce an area of a light leakage areas in the pixel unit 10.

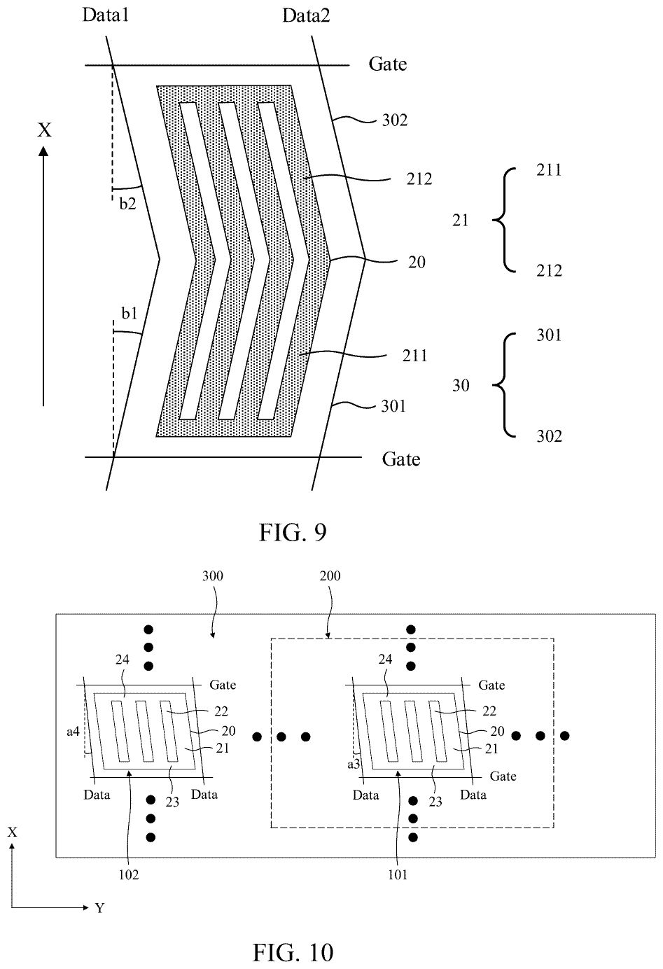

In the structure in FIG. 9, the pixel electrode 20 in FIG. 9 is a dual-domain design. The data line Data may include a plurality of data segments 30 located between two adjacent pixel units 10. The data segment 30 includes a first connection segment 301 and a second connection segment 302 that are disposed at an included angle.

This embodiment is the same as or similar to the foregoing embodiments, and a difference lies in that an included acute angle b1 between the first connection segment 301 and the first direction X and an included acute angle b2 between the second connection segment 302 and the first direction X may be different.

For example, the included acute angle b1 between the first connection segment 301 and the first direction X may be 5°, and the included acute angle b2 between the second connection segment 302 and the first direction X may be 6°. Alternatively, the included acute angle b1 between the first connection section 301 and the first direction X may be 6°, and the included acute angle b2 between the second connection section 302 and the first direction X may be 5°. In a same pixel unit 10, the included acute angles between different connection segments and the first direction X are different, so that light leakage quantities of the pixel unit 10 in different domains are different, and the brightness of the same pixel unit 10 in different domains are different. A viewing angle improvement effect is achieved by spatial mixing.

In the present application, only an included acute angle between the first connection segment 301 in the data segment 30 and the first direction X, and an included acute angle between the second connection segment 302 in the data segment 30 and the first direction X are changed. An included acute angle between the first branch 211 and the first direction X is the same as that between the second branch 212 and the first direction X. An included acute angle b1 between the first connection segment 301 and the first direction X is different from an included acute angle b2 between the second connection segment 302 and the first direction X, so as to reduce polarization scattering of light by the data lines Data. It also reduces light leakage of light on the data lines Data. It improves the brightness of a black screen of the display panel 100, and improves the contrast of the display panel 100. In addition, a brightness difference of pixel unit 10 in different domains may improve a viewing angle through spatial mixing.

In the display panel 100 in the present application, referring to FIG. 10, the display panel 100 includes a central area 200 and a peripheral area 300 located at a periphery of the central area 200. A plurality of first pixel units 101 are disposed in the central area 200, and a plurality of second pixel units 102 are disposed in the peripheral area 300.

This embodiment is the same as or similar to the foregoing embodiments, and a difference lies in that an included acute angle a3 between the branch electrode 21 and the adjacent data line Data in the first pixel unit 101 is less than an included acute angle a4 between the branch electrode 21 and the adjacent data line Data in the second pixel unit 102.

In the existing display panel 100, because the brightness of the first pixel unit 101 in the central area 200 of the display panel 100 is generally higher than the brightness of the second pixel unit 102 in the peripheral area 300, that is, the contrast of the display panel 100 in the central area 200 is generally higher than the contrast of the peripheral area 300, which results in a relatively poor contrast uniformity of each area of the display panel 100. However, in the present application, an included acute angle a3 between the branch electrode 21 and the adjacent data line Data in the first pixel unit 101 is less than an included acute angle a4 between the branch electrode 21 and the adjacent data line Data in the second pixel unit 102. That is, a tilt angle of the data line Data corresponding to the first pixel unit 101 is less than a tilt angle of the data line Data corresponding to the second pixel unit 102, which is equivalent to that a light leakage quantity of the peripheral area 300 on the data line Data is less than a light leakage quantity of the central area 200 on the data line Data. A contrast increase of the first pixel unit 101 in the peripheral area 300 is greater than a contrast increase of the second pixel unit 102 in the central area 200. This ameliorates a technical problem that the contrasts of the peripheral area 300 and the central area 200 in the display panel 100 are inconsistent, and improves a display effect of the display panel 100.

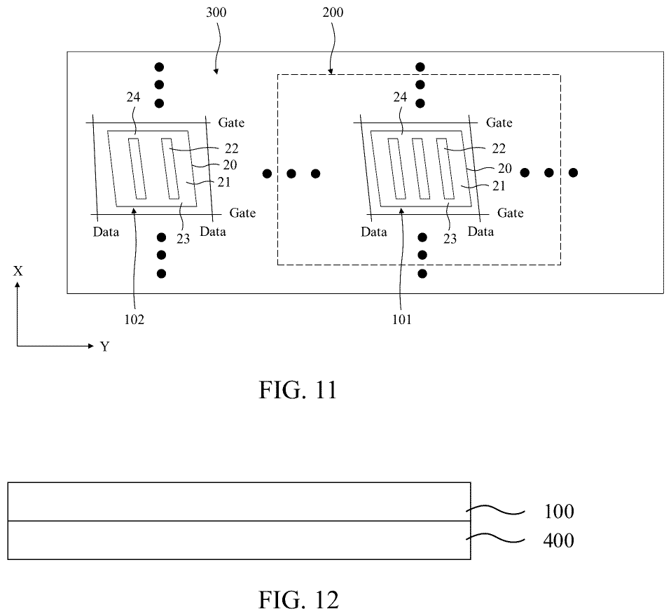

In the display panel 100 of the present application, referring to FIG. 11, this embodiment is the same as or similar to the foregoing embodiments, and a difference lies in that the number of the branch electrodes 21 in the first pixel unit 101 is greater than the number of the branch electrodes 21 in the second pixel unit 102.

In one or more embodiments, because the tilt angle of the data lines Data in the peripheral area 300 is less than the tilt angle of the data lines Data in the central area 200, the spacing between the pixel electrode 20 in the first pixel unit 101 and the adjacent data line Data is greater than the spacing between the pixel electrode 20 in the second pixel unit 102 and the adjacent data line Data. The spacing between the data line Data and the pixel electrode 20 is too small, so that a data voltage on the data line Data has a greater impact on the pixel voltage on the pixel electrode 20, that is, coupling capacitances between the data lines Data and the pixel electrodes 20 are different. However, in the present application, the number of the branch electrodes 21 in the second pixel unit 102 is reduced, that is, a transverse width occupied by the pixel electrode 20 in one pixel unit is reduced, so that the spacing between the pixel electrode 20 in the second pixel unit 102 and the adjacent data lines Data meets a design requirement, or the spacing is equal to the spacing between the pixel electrode 20 in the first pixel unit 101 and the adjacent data lines Data, so that coupling capacitances between the data lines Data and different pixel units 10 are equal.

In one or more embodiments, in a second direction Y, a width of the first pixel unit 101 is less than a width of the second pixel unit 102, and the second direction Y may be parallel to the scan line Gate and perpendicular to the first direction X. Because the spacing between the pixel electrode 20 in the second pixel unit 102 and the adjacent data line Data is too small, in the present application, the width of the second pixel unit 102 is increased, so that the spacing between the pixel electrode 20 in the second pixel unit 102 and the adjacent data line Data meets a design requirement, or the spacing is equal to the spacing between the pixel electrode 20 in the first pixel unit 101 and the adjacent data line Data, so that coupling capacitances between the data lines Data and the different pixel units 10 are equal.

In the display panel 100 in the present application, the data line Data includes a first metal layer, a second metal layer, and a third metal layer disposed in a stack, and a material of the second metal layer includes aluminum.

In one or more embodiments, the data line Data includes a metal. An electric field that may scatter light and change a vibration direction exists at an edge of the data line Data. The high-frequency light field may form polarized plasma-stimulated light on a metal sidewall. A larger metal conductivity indicates a stronger plasma-stimulated light. For example, a conductivity of metal aluminum is less than a conductivity of metal copper, and a scattering of metal aluminum is less than that of metal copper.

In one or more embodiments, materials of the first metal layer and the third metal layer may be metal titanium.

Referring to FIG. 12, the present application further provides a display apparatus. The display apparatus includes the above-mentioned display panel 100 and a backlight module 400 disposed on a side of the display panel 100. In one or more embodiments, a working principle of the display apparatus is the same as or similar to a working principle of the display panel, and details will not be described herein again. The display apparatus may be but is not limited to a mobile phone, a computer, a laptop, or the like.

It may be understood that, a person of ordinary skill in the art may perform equivalent replacement or change according to the technical solutions of the present application and the inventive concept thereof, and all such changes or replacement shall fall within the protection scope of the claims annexed to the present application.

What is claimed is:

1. A display panel, comprising a plurality of data lines and a plurality of scan lines, wherein the plurality of data lines and the plurality of scan lines enclose a plurality of pixel units, and each of the pixel units comprises a pixel electrode, and wherein the pixel electrode comprises a plurality of slits and a plurality of branch electrodes disposed between the plurality of slits, and an included acute angle between a branch electrode of the plurality of branch electrodes and an adjacent data line of the data lines is greater than 0° and less than or equal to 7°.

2. The display panel according to claim 1, wherein an included acute angle between the branch electrode and a first direction is 7°, an included acute angle between the data line and the first direction is greater than or equal to 0° and less than 7°, and the first direction is perpendicular to the scan lines.

3. The display panel according to claim 2, wherein in one of the pixel units, the pixel electrode further comprises an edge electrode disposed between the data line and the branch electrode, and the edge electrode and the branch electrode are electrically connected; and
wherein the edge electrode and the branch electrode are disposed in parallel and separately, and a length of the edge electrode is less than a length of the branch electrode in an extension direction of the branch electrode.

4. The display panel according to claim 3, wherein in the pixel unit, the pixel electrode further comprises a first transverse electrode and a second transverse electrode; and
wherein a first end of each of the plurality of branch electrodes is connected to the first transverse electrode, a second end of each of the plurality of branch electrodes is connected to the second transverse electrode, a first end of the edge electrode is connected to the first transverse electrode, and a second end of the edge electrode and the second transverse electrode are disposed separately.

5. The display panel according to claim 4, wherein a length of the first transverse electrode and a length of the second transverse electrode in the extension direction of the scanning line are equal.

6. The display panel according to claim 4, wherein a spacing between the edge electrode and an adjacent one of the branch electrodes is less than a width of one of the slits.

7. The display panel according to claim 4, wherein the pixel electrode comprises one said edge electrode disposed between the data line and the branch electrode; and
wherein in the extension direction of the branch electrode, a length of the edge electrode is less than half a length of the branch electrode.

8. The display panel according to claim 4, wherein the pixel electrode comprises two said edge electrodes disposed between the data line and the branch electrode; and
wherein in the extension direction of the branch electrode, lengths of the two edge electrodes are less than a length of the branch electrode, and the length of the edge electrode close to the branch electrode is greater than the length of the edge electrode away from the branch electrode.

9. The display panel according to claim 2, wherein the branch electrode comprises a first branch and a second branch, and the first branch and the second branch are disposed at an included angle; and
wherein an included acute angle between the first branch and the first direction is the same as an included acute angle between the second branch and the first direction.

10. The display panel according to claim 9, wherein the data line comprises a plurality of data segments located between two adjacent pixel units of the pixel units, each of the data segments comprise a first connection segment and a second connection segment disposed at an included angle, the first branch is corresponding to the first connection segment, and the second branch is corresponding to the second connection segment; and
wherein an included acute angle between the first connection segment and the first direction is different from an included acute angle between the second connection segment and the first direction.

11. The display panel according to claim 2, wherein the display panel comprises a central area and a peripheral area located at a periphery of the central area, a plurality of first pixel units among the pixel units are disposed in the central area, and a plurality of second pixel units among the pixel units are disposed in the peripheral area; and
wherein an included acute angle between the branch electrode in the first pixel unit and an adjacent one of the data lines is less than an included acute angle between the branch electrode in the second pixel unit and an adjacent one of the data lines.

12. The display panel according to claim 11, wherein the number of the branch electrodes in the first pixel unit is greater than the number of the branch electrodes in the second pixel unit.

13. The display panel according to claim 11, wherein in a second direction perpendicular to the first direction, a width of one of the first pixel units is less than a width of one of the second pixel units.

14. The display panel according to claim 2, wherein the display panel further comprises a light shielding layer covering the data lines and some of the pixel units; and
wherein a boundary of the light shielding layer and a boundary of an adjacent one of the branch electrodes are not disposed in parallel.

15. A display apparatus, comprising a display panel and a backlight module disposed on one side of the display panel; wherein the display panel comprises a plurality of data lines and a plurality of scan lines, the plurality of data lines and the plurality of scan lines enclose a plurality of pixel units, and each of the pixel units comprises a pixel electrode; and
wherein the pixel electrode comprises a plurality of slits and a plurality of branch electrodes disposed between the plurality of slits, and an included acute angle between a branch electrode of the plurality of branch electrodes and an adjacent data line of the data lines is greater than 0° and less than or equal to 7°.

16. The display apparatus according to claim 15, wherein an included acute angle between the branch electrode and a first direction is 7°, an included acute angle between the data line and the first direction is greater than or equal to 0° and less than 7°, and the first direction is perpendicular to the scan lines.

17. The display apparatus according to claim 16, wherein the branch electrode comprises a first branch and a second branch, and the first branch and the second branch are disposed at an included angle; and
wherein an included acute angle between the first branch and the first direction is the same as an included acute angle between the second branch and the first direction.

18. The display apparatus according to claim 17, wherein the data line comprises a plurality of data segments located between two adjacent pixel units of the pixel units, each of the data segments comprise a first connection segment and a second connection segment disposed at an included angle, the first branch is corresponding to the first connection segment, and the second branch is corresponding to the second connection segment; and
wherein an included acute angle between the first connection segment and the first direction is different from an included acute angle between the second connection segment and the first direction.

19. The display apparatus according to claim 18, wherein the display panel further comprises a light shielding layer covering the data lines and some of the pixel units; and
wherein a boundary of the light shielding layer and a boundary of an adjacent one of the branch electrodes are not disposed in parallel.

20. The display apparatus according to claim 16, wherein in one of the pixel units, the pixel electrode further comprises an edge electrode disposed between the data line and the branch electrode, and the edge electrode and the branch electrode are electrically connected; and
wherein the edge electrode and the branch electrode are disposed in parallel and separately, and a length of the edge electrode is less than a length of the branch electrode in an extension direction of the branch electrode, and a spacing between the edge electrode and an adjacent one of the branch electrodes is less than a width of one of the slits.
